(19) United States
(12) Patent Application Publication
(10) Pub. No.: US 2003/0002242 A1
(43) Pub. Date: Jan. 2, 2003

(54) Removable bezel for personal computer

(76) Inventor: Deng-Hsi Chen, Keelung (TW)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/883,226

(22) Filed: Jun. 19, 2001

(51) Int. Cl. H05K 5/00

(52) U.S. Cl. 361/683

(57) ABSTRACT

A removable bezel for personal computer is a bezel mounted in the front side of the chassis of personal computer. The improvement of the device is in that a plurality of slots arranged on the inner surface of the bezel. A bolt is inserted into each slot. A plurality of rectangular holes is disposed on the front side of the chassis, corresponding to the location of the bolt. A lock socket is installed on each rectangular hole. According to the structure mentioned above, the bezel is fastened on the chassis by the bolt on the inner surface thereof hooked with the lock socket on the front side of the chassis. Thus the bezel can be removed directly from the front side of the chassis conveniently.

### BACKGROUND OF THE INVENTION

1. Field of the Invention

The invention relates to a removable bezel for personal computer, especially to a bezel fastened by bolts on the inner side thereof hooked with lock sockets on the chassis of the personal computer for easy assembling and removing of the bezel.

2. Description of the Prior Art

The general housing of computer includes a chassis, a cover and a bezel. A disk bay is installed in the front side of the chassis for accommodating various kind of disk devices such as FDD (floppy disk drive), HDD (hard disk drive), CDROM (compact disk read-only memory) and removable HDD. The motherboard is disposed on the frame inside the housing.

When disposing various kind of disk devices, each disk device is inserted through the bezel and put into the disk bay. Screws are used on two lateral sides of the disk bay for fastening the disk device. The front side of the disk device is integrated into the bezel and become part of the bezel.

The general way for fixing the bezel is by screws or by a plurality of protruding rods mounted on the inner surface of the bezel melt into rivet shape after being inserting through the hole on the chassis. While the bezel fastened on the chassis by these ways is inconvenient for assembling and removing, not only laborious but also time-consuming.

### SUMMARY OF THE INVENTION

It is therefore a primary object of the present invention to provide a removable bezel for personal computer which is fastened by the bolt on the inner surface thereof hooked with the lock socket mounted on the front side of the chassis so as to be removed and assembled easily.

### BRIEF DESCRIPTION OF THE DRAWINGS

The accomplishment of the above-mentioned object of the present invention will become apparent from the following description and its accompanying drawings which disclose illustrative an embodiment of the present invention, and are as follows:

FIG. 1 is a perspective view of a removable bezel for personal computer in accordance with the present invention;

FIG. 2 is an explosive view of the present invention;

FIG. 3 is a partial perspective view of a bolt installed on a bezel in accordance with the present invention;

FIG. 4 is partial perspective view of a lock socket installed on a chassis according to the present invention.

### DETAILED DESCRIPTION OF THE PREFERRED EMBODIMENT

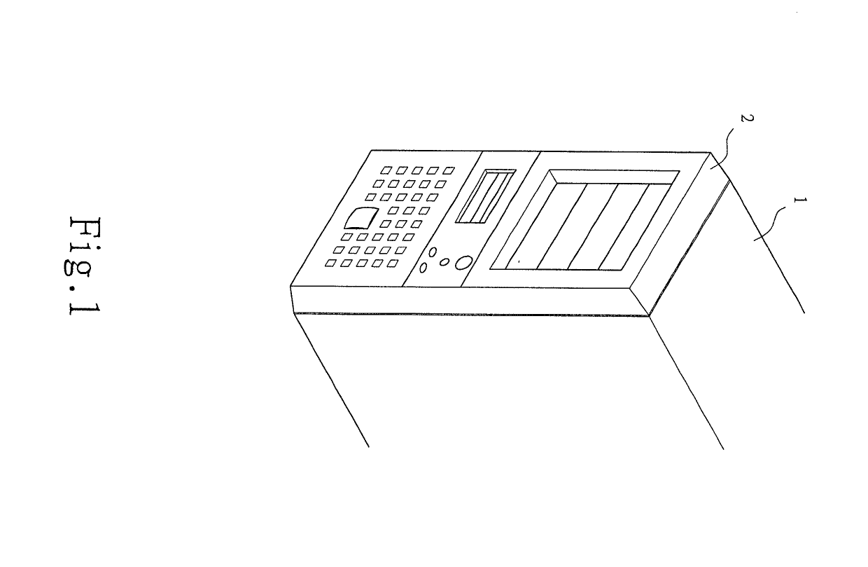

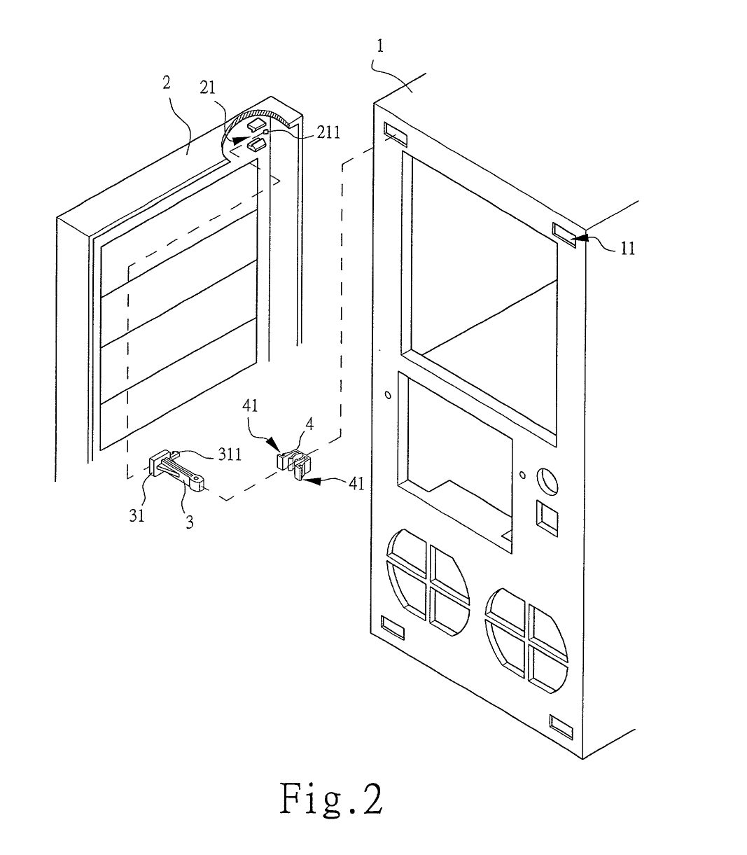

Refer to FIG. 1 & FIG. 2, the present invention is composed of a chassis 1 mounted in the front side of a bezel 2. A plurality of slots 21 is arranged on the inner side of the bezel 2. Corresponding to each slot, a bolt 3 is inserted into the slot 21. A plurality of rectangular hole 11 is installed in the front side of the chassis 1 on the location corresponding to the bolt 3 for accommodating lock sockets 4. According to the structure above, the bezel 2 is connected with the chassis 1 firmly by the bolt 3 on the inner surface of the chassis 2 hooked with the lock socket 4 on the front side of the chassis 1. Since the bezel 2 is fastened by the bolt 3 hooked with the lock socket 4, the bezel 2 can be pulled out from the chassis 1 directly for easy assembling and removing. Thus the manufacturing cost is reduced and the products are more competitive.

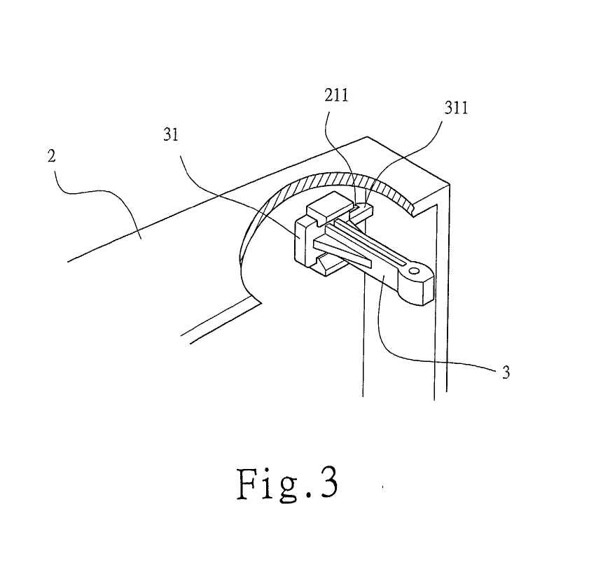

Refer to FIG. 2 and FIG. 3, the bolt 3 includes an inserted board 31 on the bottom side thereof, and a hook 311 installed on the lateral side of the inserted board 31. A pin 211 is arranged on the lateral side of the slot 21 on the bezel 2. The inserted board 31 on the bottom of the bolt 3 is inserted into the slot 21 on the bezel 2 and the hook 311 on the lateral side of the inserted board 31 is hooked with the pin 211 on the lateral side of the slot 21. Thus the bolt 3 is fastened on the slot 21.

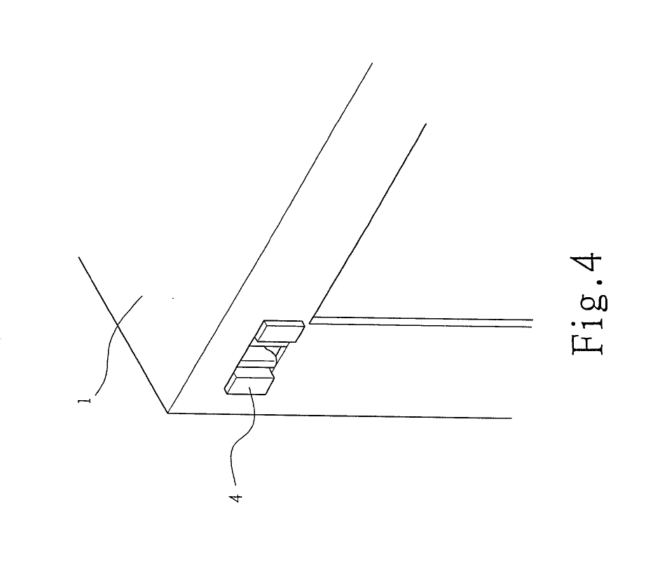

With reference of FIG. 2 and FIG. 4, the lock socket 4 is Ω-shaped with two flutes 41 arranged on two lateral sides respectively. The lock socket 4 is installed on the rectangular hole 11 by the two flutes 41 hooked with two lateral sides of the rectangular hole 11.

It should be noted that the above description and accompanying drawings are only used to illustrate some embodiments of the present invention, not intended to limit the scope thereof. Any modification of the embodiments should fall within the scope of the present invention.

1. A removable bezel for personal computer comprising
a bezel mounted in the front side of a chassis of personal computer,
a plurality of slot, a plurality of bolt, a plurality of rectangular hole, a plurality of lock socket,
wherein a plurality of said slots is arranged on the inner surface of said bezel with a bolt inserted into each slot;
a plurality of said rectangular holes is disposed on the front side of said chassis, corresponding to the location of said bolt;
said lock socket is installed on each said rectangular hole;
thereby said bezel is fastened on said chassis by said bolt on the inner surface of said bezel hooked with said lock socket on the front side of said chassis.

2. A removable bezel for personal computer as claimed in claim 1, wherein said bolt includes an inserted board on the bottom thereof, a hook on the lateral side; while a pin is arranged on the lateral side of said slot on said bezel; said inserted board is inserted into said slot on said bezel and said hook is hooked with said pin on lateral side of said slot for fixing said bolt firmly on said slot.

3. A removable bezel for personal computer as claimed in claim 1, wherein said lock socket is Ω-shaped with two flutes arranged on two lateral sides thereof respectively; said flute is used for hooked with the lateral side of said rectangular hole on said chassis so as to fasten said lock sockets on said rectangular holes.
